(19) United States
(12) Patent Application Publication
(10) Pub. No.: US 2012/0266463 A1
(43) Pub. Date: Oct. 25, 2012

(54) METHOD FOR MANUFACTURING PRINTED CIRCUIT BOARD

(75) Inventors: Chang Bo LEE, Busan (KR); Cheol Ho CHOI, Gyunggi-do (KR); Jin Ho KIM, Gyunggi-do (KR); Jee Soo MOK, Gyunggi-do (KR)

(73) Assignee: SAMSUNG ELECTRO-MECHANICS CO., LTD., Gyunggi-do (KR)

(21) Appl. No.: 13/252,815

(22) Filed: Oct. 4, 2011

(30) Foreign Application Priority Data
Apr. 25, 2011 (KR) 10-2011-0038555

(51) Int. Cl. H05K 3/10

(52) U.S. Cl. 29/846

(57) ABSTRACT

Disclosed herein is a method for manufacturing a printed circuit board, including: forming a complex solder resist layer including a solder resist having an open part for forming a metal post and a cover film contacting the solder resist on a base substrate having an outer-layer circuit including a plating lead line; forming a metal post on the open part for forming the metal post by performing electroplating; removing the plating lead line; and exposing the metal post by removing the cover film.

### CROSS REFERENCE TO RELATED APPLICATION

This application claims the benefit of Korean Patent Application No. 10-2011-0038555, filed on Apr. 25, 2011, entitled “Method for Manufacturing Printed Circuit Board”, which is hereby incorporated by reference in its entirety into this application.

### BACKGROUND OF THE INVENTION

1. Technical Field

The present invention relates to a method for manufacturing a printed circuit board.

2. Description of the Related Art

Recently, with the development of electronic industries, a demand for high-performance, multi-functional, and small-sized electronic parts has increased. As a result, a demand for a technology capable of implementing high integration, thinness, micro circuit patterns of a substrate for surface-mounting parts, such as a system in package (SIP), a 3D package, or the like, has also increased.

In particular, as technologies of mounting electronic parts on a surface of a substrate, a wire bonding method and a flip chip bonding method have been used so as to electrically connect semiconductor chips to a printed circuit board. However, since the wire bonding method connects the semiconductor chips to the printed circuit board using the wires, a size of a module is increased, an additional process is required, and it is difficult to implement a fine pitch of circuit patterns. As a result, the flip chip bonding method has been mainly used.

The flip chip bonding method forms external connection terminals (that is, a bump) made of gold, solder, or other metals, and the like, and having a size in a range of several tens of μm to several hundreds of μm on the semiconductor chip. Further, unlike the surface-mounting method according to the existing wire bonding technology, the flip chip bonding method flips the semiconductor chip on which the bump is formed to mount the surface of the semiconductor chip toward the substrate.

However, the flip chip bonding method has ultimately been developed for a new structure using a metal post so as to implement an ultra-fine pitch of the circuit pattern.

The reason is that a general bump (lead (Pb) base) has thermal flexibility such that it is difficult to implement a bump interval with a fine pitch due to a short, or the like. That is, the fine pitch may be implemented by replacing the rigid metal post with the general bump having thermal flexibility.

FIGS. 9 to 17 are process cross-sectional views sequentially showing a method for manufacturing a printed circuit board according to the prior art.

First, as shown in FIG. 9, a solder resist layer 20 is formed on a base substrate 10 having an outer-layer circuit 11.

Next, as shown in FIG. 10, a patterned mask (not shown) is disposed on the formed solder resist layer 20 and then, solder resists corresponding to an open part 23 for forming a metal post and an open part 25 for exposing a connection pad are removed by using a photolithography method including exposure and development processes.

Next, as shown in FIG. 11, seed layers 30 are formed on the solder resist layer 20 by using an electroless plating process, including the inner walls of the open part 23 for forming the metal post and the open part 25 for exposing the connection pad. In this configuration, the seed layer 30 is formed to perform electroplating for forming a metal post 50 during subsequent processes.

Next, as shown in FIG. 12, a photosensitive resist 40 is laminated on the formed seed layer 30 and as shown in FIG. 13, an open part 45 is formed by removing the photosensitive resist corresponding to the open part 23 for forming the meal post using the photolithography method including the exposure and development processes.

Next, as shown in FIG. 14, the metal post 50 is formed on the open part 45 by performing electroplating.

Next, as shown in FIG. 15, in order to planarize the surface of the metal post 50, the metal post 50 is polished by a predetermined thickness from a top surface of the photosensitive resist 40 and as shown in FIG. 16, the photosensitive resist 40 is delaminated and then, as shown in FIG. 17, the seed layer 30 is removed using a flash etching process, or the like.

As described above, in the method for manufacturing the printed circuit board according to the prior art, the open part for forming the metal post is formed by first exposing/developing the solder resist layer and then, forming and exposing/developing the to photosensitive resist layer, such that the exposure/development processes are performed two times. Further, the process of forming the seed layer for performing the electroplating on the solder resist layer is performed prior to forming the photosensitive resist layer, such that process efficiency may be degraded due to the increase in the number of processes.

In addition, the open part for forming the metal post is formed by performing the exposure/development process two times in total, that is, once in the solder resist layer and once again in the photosensitive resist layer, such that the alignment of the open parts formed on each of the two layers may not be easily performed.

### SUMMARY OF THE INVENTION

The present invention has been made in an effort to provide a method for manufacturing a printed circuit board capable of reducing the number of processes forming a metal post so as to improve process efficiency.

In addition, the present invention has been made in an effort to provide a method for manufacturing a printed circuit board capable of usefully implementing a fine bump pitch by improving alignment characteristics of an open part for forming metal posts formed on a solder resist layer and a plating resist layer.

According to a preferred embodiment of the present invention, there is provided a method for manufacturing a printed circuit board, including: forming a complex solder resist layer including a solder resist having an open part for forming a metal post and a cover film contacting the solder resist on a base substrate having an outer-layer circuit including a plating lead line; forming a metal post on the open part for forming the metal post by performing electroplating; removing the plating lead line; and exposing the metal post by removing the cover film.

The open part for forming the metal post may be formed by including: forming the complex solder resist layer on the base substrate including the outer-layer circuit; disposing a mask on the complex solder resist layer, a portion of the mask corresponding to the open part for forming the metal post being patterned; and removing the complex solder resist layer corresponding to the open part for forming the metal post using laser.

The laser may include at least any one of a CO₂ laser and a YAG laser.

The removing of the plating lead line may include: forming an open part for exposing the plating lead line on the complex solder resist layer by using the laser; and removing the exposed plating lead line by performing a flash etching process.

The removing of the plating lead line may include: forming an open part for exposing the plating lead line on the complex solder resist layer using the laser; and cutting and removing the exposed plating lead line by performing a routing, punching, or drilling process.

The method for manufacturing a printed circuit board may further include, after the removing of the plating lead line, forming an open part for exposing a pad part connected to an external device using laser.

The method for manufacturing a printed circuit board may further include, after the forming of the open part for exposing the pad part, performing polishing for planarizing a top surface of the metal post.

The polishing may be performed by mechanical polishing, chemical polishing, or chemical-mechanical polishing.

The solder resist and the cover film may have the same thermodegradation.

The solder resist and the cover film may be bonded to each other by a foaming adhesive member.

The cover film may be removed by a mechanical delamination process or a chemical delamination process.

The method for manufacturing a printed circuit board may further include, after the exposing of the metal post, forming a surface treatment layer on the top surface of the metal post.

### BRIEF DESCRIPTION OF THE DRAWINGS

FIGS. 1 to 8 are process cross-sectional views sequentially showing a method for manufacturing a printed circuit board according to a preferred embodiment of the present invention.

FIGS. 9 to 17 are process cross-sectional views sequentially showing a method for manufacturing a printed circuit board according to the prior art.

### DESCRIPTION OF THE PREFERRED EMBODIMENTS

Various features and advantages of the present invention will be more obvious from the following description with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted. Terms used in the specification, ‘first’, ‘second’, etc., can be used to describe various components, but the components are not to be construed as being limited to the terms.

Hereinafter, preferred embodiments of the present invention will be described in detail with reference to the accompanying drawings.

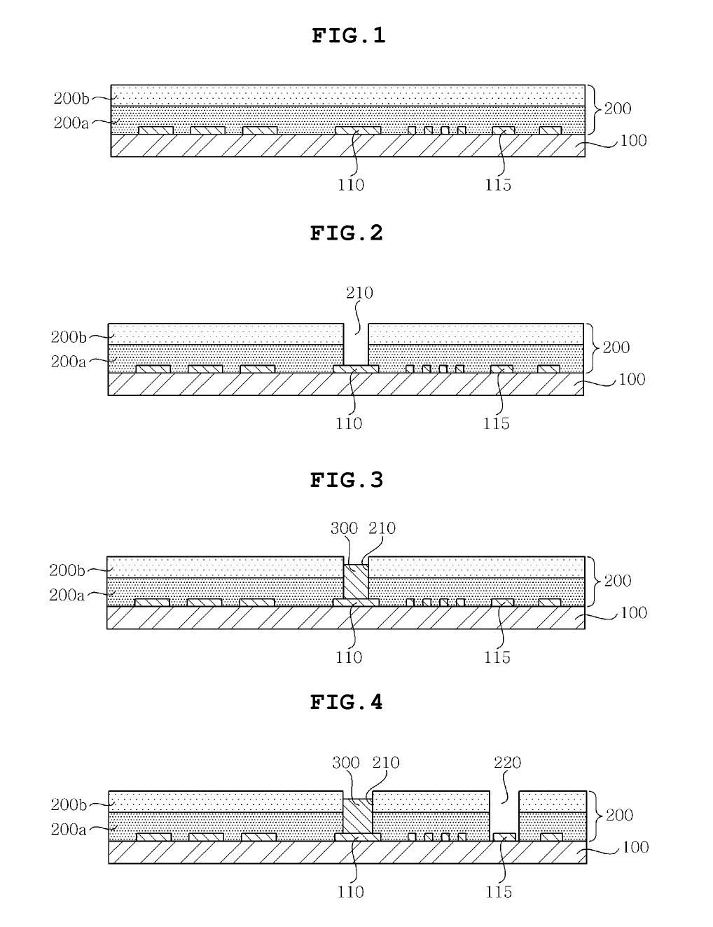

FIGS. 1 to 8 are process cross-sectional views showing a method for manufacturing a printed circuit board according to a preferred embodiment of the present invention.

FIGS. 1 to 8 schematically show other components of the printed circuit board other than characterizing parts of the preferred embodiment rather than showing in detail the components. Those skilled in the art can sufficiently recognize that the method for manufacturing a printed circuit board according to the preferred embodiment of the present invention may be applied to all of the printed circuit boards well known to the art without being specifically limited.

Hereinafter, preferred embodiments of the present invention will be described in more detail but the scope of the present invention is not limited thereto.

First, as shown in FIG. 1, a complex solder resist layer 200 is formed on a base substrate 100 having an outer-layer circuit 110 including a plating lead line 115.

In the preferred embodiment of the present invention, the outer-layer circuit 110 is formed on one surface of the base substrate 100 but may also be formed on both surfaces.

The base substrate 100 may be a multi-layer printed circuit board on which a plurality of insulating layers and a plurality of circuit layers are laminated.

As the insulating layer, a resin insulating layer may be used. As the resin insulating layer, a thermosetting resin such as epoxy resin, a thermoplastic resin such as polyimide, a resin in which a reinforcement material, such as a glass fiber or an inorganic filler, is impregnated in the thermosetting resin and the thermoplastic resin, for example, a prepreg may be used and the thermosetting resin and/or a photocurable resin, or the like, may also be used. However, the preferred embodiment of the present invention is not specifically limited thereto.

The outer-layer circuit 110 and the circuit layer may be used as a conductive metal for a circuit in a field of a circuit board without being limited. In the printed circuit board, copper may be typically used.

The complex solder resist layer 200 may include a solder resist 200a contacting a top surface of the base substrate 100 and a cover film 200b contacting the solder resist 200a, but is not specifically limited thereto.

That is, as shown in FIG. 1, in the preferred embodiment of the present invention, the case in which a solder resist of two layers is laminated as the complex solder resist layer 200, but a solder resist of three layers or more may also be laminated.

In the preferred embodiment of the present invention, both of the solder resist 200a and the cover film 200b may be made of a film material or only the cover film 200b may be made of a film material, but is not specifically limited thereto.

In addition, the solder resist 200a and the cover film 200b may be made of different materials or the same material.

In addition, the solder resist 200a and the cover film 200b may be made to have the same thermodegradation. In this case, the same thermodegradation means that the solder resist 200a and the cover film 200b have substantially the same thermodegradation.

As described above, the solder resist 200a and the cover film 200b have the same thermodegradation, such that the solder resist 200a and the cover film 200b are thermodegraded at a uniform speed when forming an open part 210 for forming a metal post using a laser during subsequent processes, thereby relatively uniformly forming diameters of a top and a bottom of the open part 210.

In addition, a separate foaming adhesive member may be included or may not be included between the solder resist 200a and the cover film 200b. In this case, a volume of the foaming adhesive member is expanded at a specific temperature such as high temperature or low temperature to make releasability of the solder resist 200a and the cover film 200b good, thereby easily separating the solder resist 200a from the cover film 200b during the subsequent processes.

In addition, the solder resist 200a or the cover film 200b containing a foaming to material may also be used, without including a separate foaming adhesive member between the solder resist 200a and the cover film 200b.

In addition, in the preferred embodiment of the present invention, the complex solder resist layer 200 in which the solder resist 200a and the cover film 200b are sequentially formed on the top surface of the base substrate 100 or the solder resist 200a and the cover film 200b are integrally formed may also be formed on the top surface of the base substrate 100.

In this case, if both of the solder resist 200a and the cover film 200b are made of a film material, they may be formed on the base substrate 100 using a vacuum lamination process. If both of the solder resist 200a and the cover film 200b are made of an ink material, they may be formed using a screen printing method, a roll coating method, a curtain coating method, a spray method, or the like.

In this case, each formation method is well known to those skilled in the art and therefore, will be omitted.

Next, as shown in FIG. 2, the open part 210 for forming the metal post is formed on the complex solder resist layer 200 formed on the base substrate 100.

In the preferred embodiment of the present invention, the complex solder resist layer 200 is cured and then, the cured complex solder resist layer 200 is selectively removed using the laser according to the solder resist mask pattern, thereby forming the open part 210 for forming the metal post. In this case, the laser includes a CO₂ laser drill, a YAG laser drill, or the like, but is not particularly limited thereto.

As described above, the solder resistor 200a and the cover film 200b on the complex solder resist layer 200 have substantially the same thermodegradation, such that the degradation by laser heat is uniformly performed during the laser process, thereby relatively uniformly forming the diameters of the top and the bottom of the open part 210 for forming the metal post.

Next, as shown in FIG. 3, the metal post 300 is formed by performing an electroplating process on the open part 210 for forming the metal post.

In this case, the electroplating process may be performed by applying current to the pre-formed plating lead line 115, together with the outer-layer circuit 110 on the base substrate 100.

Next, as shown in FIG. 4, an open part 220 for exposing the plating lead line 115 is formed on the complex solder resist layer 200.

In this case, the open part 220 is performed using the laser process. The laser includes the CO₂ laser drill, the YAG laser drill, or the like, but is not particularly limited thereto.

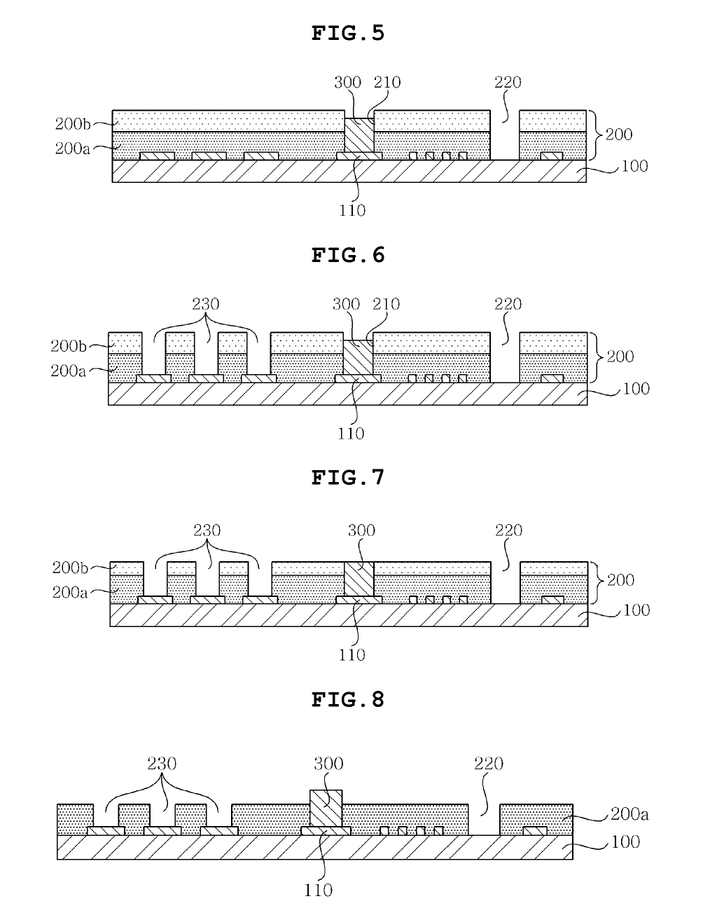

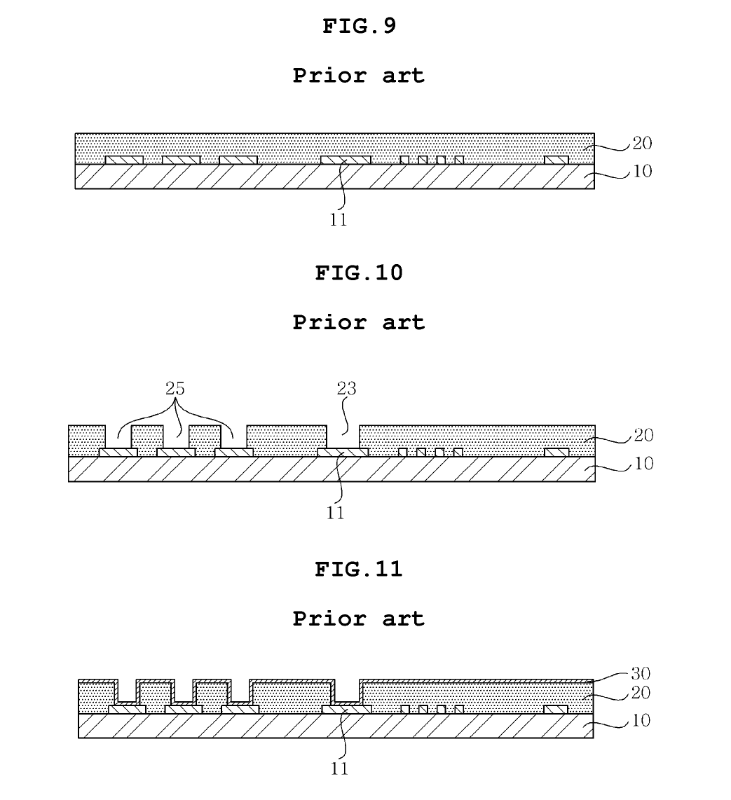

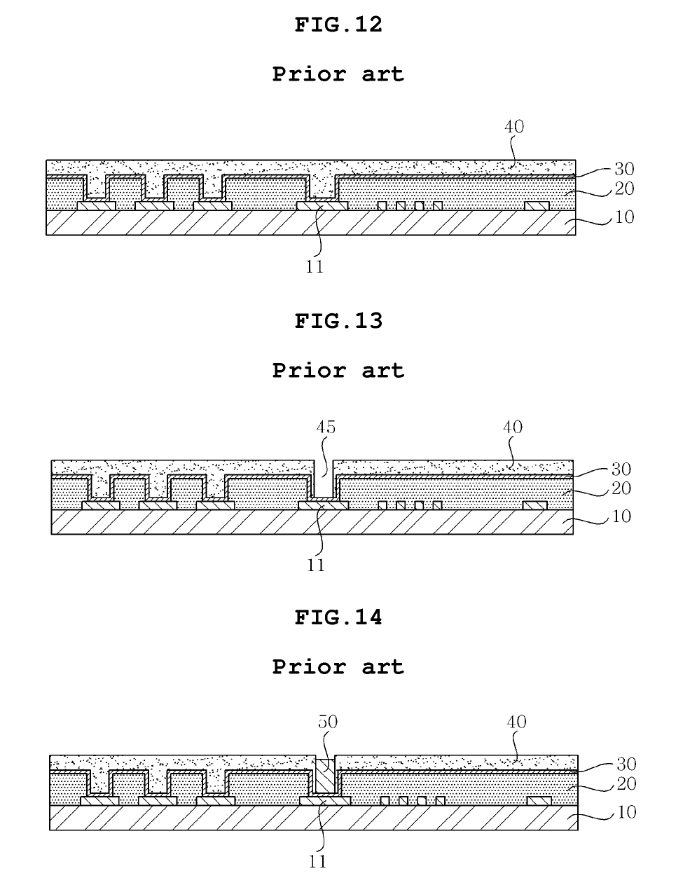

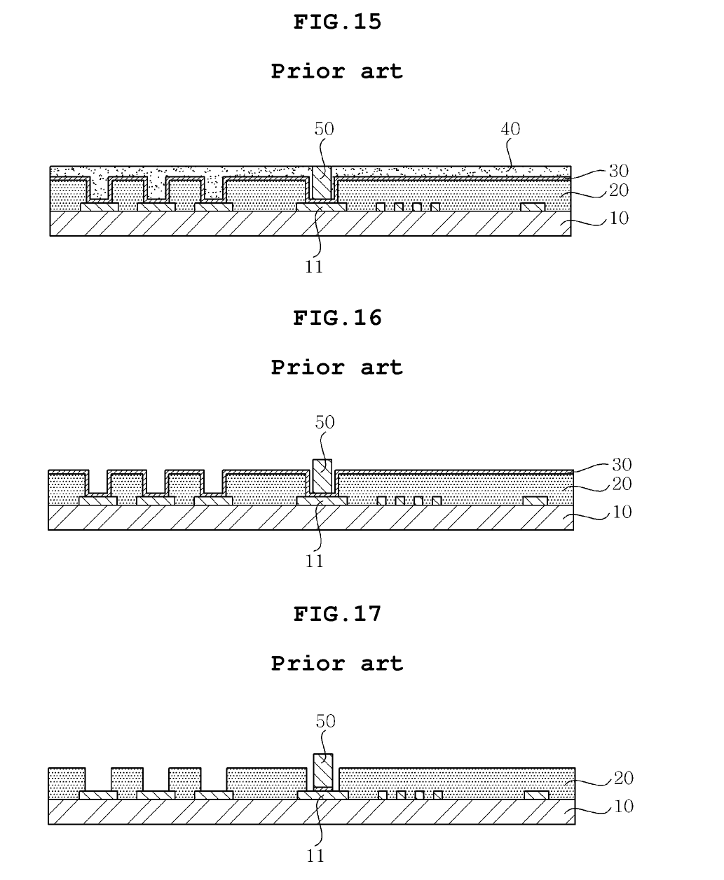

Next, as shown in FIG. 5, the exposed plating lead line 115 is removed.

In this case, in the preferred embodiment of the present invention, the plating lead line 115 may be removed using a flash etching process.

Alternatively, the plating lead line 115 may be removed by being cut by punching, routing, or drilling processes, but is not particularly limited thereto.

Next, as shown in FIG. 6, an open part 230 for exposing a connection pad is formed on the complex solder resist layer 200.

A solder bump as an external connection terminal is formed on the connection pad exposed by the open part 230 during the subsequent processes. In this case, semiconductor devices or external parts are electrically connected with inner-layer circuits through the solder bump.

Next, as shown in FIG. 7, in order to planarize the top surface of the metal post 300, the polishing is performed in a thickness direction from the top surface of the complex solder resist layer 200, that is, the top surface of the cover film 200b including the metal post 300.

The preferred embodiment of the present invention shows that only one metal post 200 is formed, but at least two metal posts 200 may be formed. The planarizing process is performed so as to make the heights of the plurality of metal posts 200 uniform.

In this case, the polishing may include a mechanical polishing method, a chemical polishing method, and a chemical-mechanical polishing method, but is not particularly limited thereto.

Next, as shown in FIG. 8, in the complex solder resist layer 200, the cover film 200b is delaminated from the solder resist 200a to expose the metal post 300.

As described above, in the preferred embodiment of the present invention, the foaming adhesive member is present between the solder resist 200a and the cover film 200b. The volume of the foaming adhesive member is expanded by applying heat of a specific temperature to the printed circuit board to improve the releasability, thereby mechanically and easily delaminating the cover film 200b from the solder resist 200a.

In addition, the cover film 200b may also be delaminated from the solder resist 200a by performing the delamination process using chemicals.

As described, a portion of the metal post 300 is exposed so as to be protruded from the solder resist 200a, thereby further improving the adhesion at the time of connecting with the external devices.

In addition, after delaminating the cover film 200b, a surface treatment layer (not shown) may be further formed on the top surface of the exposed metal post 300 and the top surface of the connection pad exposed by the open part 230, if necessary.

The surface treatment layer may be formed by technologies well known in the art without being limited. For example, the surface treatment layer may be formed by an electro gold plating, immersion gold plating, organic solderability preservative (OSP), immersion tin plating, immersion silver plating, electroless nickel and immersion gold (ENIG), direct immersion gold (DIG) plating, hot air solder leveling (HASL), or the like.

Forming the surface treatment layer may improve the adhesion between the connection pad and the metal post 300 and the external devices during the subsequent processes.

As set forth above, the preferred embodiment of the present invention can form a plating lead line at the time of forming an outer-layer circuit and then, form the metal post using the plating lead line, such that there is no need to form a separate seed layer for electroplating, thereby reducing the number of processes and thus, improving process efficiency.

Further, the preferred embodiment of the present invention can form the open part for forming the metal post on both of the solder resist and the cover film, thereby reducing the number of processes and thus, improving process efficiency and can process the open part at one time using the laser, thereby improving the alignment characteristics and thus, usefully implementing the fine bump pitch.

Although the embodiment of the present invention has been disclosed for illustrative purposes, it will be appreciated that a method for manufacturing a printed circuit board according to the invention is not limited thereby, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A method for manufacturing a printed circuit board, comprising:
forming a complex solder resist layer including a solder resist having an open part for forming a metal post and a cover film contacting the solder resist on a base substrate having an outer-layer circuit including a plating lead line;
forming a metal post on the open part for forming the metal post by performing electroplating;
removing the plating lead line; and
exposing the metal post by removing the cover film.

2. The method as set forth in claim 1, wherein the open part for forming the metal post is formed by including:
forming the complex solder resist layer on the base substrate including the outer-layer circuit;
disposing a mask on the complex solder resist layer, a portion of the mask corresponding to the open part for forming the metal post being patterned; and
removing the complex solder resist layer corresponding to the open part for forming the metal post using laser.

3. The method as set forth in claim 2, wherein the laser includes at least any one of a CO₂ laser and a YAG laser.

4. The method as set forth in claim 1, wherein the removing of the plating lead line includes:
forming an open part for exposing the plating lead line on the complex solder resist layer by using the laser; and
removing the exposed plating lead line by performing a flash etching process.

5. The method as set forth in claim 1, wherein the removing of the plating lead line includes:
forming an open part for exposing the plating lead line on the complex solder resist layer using the laser; and
cutting and removing the exposed plating lead line by performing a routing, punching, or drilling process.

6. The method as set forth in claim 1, further comprising after the removing of the plating lead line, forming an open part for exposing a pad part connected to an external device using laser.

7. The method as set forth in claim 6, further comprising after the forming of the open part for exposing the pad part, performing polishing for planarizing a top surface of the metal post.

8. The method as set forth in claim 7, wherein the polishing is performed by mechanical polishing, chemical polishing, or chemical-mechanical polishing.

9. The method as set forth in claim 1, wherein the solder resist and the cover film have the same thermodegradation.

10. The method as set forth in claim 1, wherein the solder resist and the cover film are bonded to each other by a foaming adhesive member.

11. The method as set forth in claim 1, wherein the cover film is removed by a mechanical delamination process or a chemical delamination process.

12. The method as set forth in claim 1, further comprising after the exposing of the metal post, forming a surface treatment layer on the top surface of the metal post.
